(19) United States
(12) Patent Application Publication
(10) Pub. No.: US 2014/0343907 A1
(43) Pub. Date: Nov. 20, 2014

(54) METHOD AND SYSTEM FOR BUILDING AT LEAST ONE AIRCRAFT GUIDELINE IN AN AIRPORT NAVIGATION NETWORK

(71) Applicant: Thales, Neuilly Sur Seine (FR)

(72) Inventors: Pierre GAMET, TOULOUSE (FR); Rémy AULETTO, TOULOUSE (FR)

(73) Assignee: THALES, Neuilly Sur Seine (FR)

(21) Appl. No.: 14/274,984

(22) Filed: May 12, 2014

(30) Foreign Application Priority Data
May 15, 2013 (FR) 13 01122

(51) Int. Cl. G06F 17/50

(52) U.S. Cl. CPC G06F 17/5009
USPC 703/2

(57) ABSTRACT

This building method concerns building of at least one aircraft guideline in an airport navigation network. The navigation network includes a plurality of polygons and is associated with an airport area including taxiways, each guideline connecting two distinct sides of a corresponding polygon, the navigation network being configured to be stored in a memory of a computer system. The method is implemented by a computer and includes the following steps creating nodes at each intersection between an existing guideline and a side of a corresponding polygon, or at the middle of a side shared by two polygons when no guideline is secant with said side, detecting at least one pair of nodes not connected by a guideline, computing, for each detected pair of nodes, a guideline in the form of a polynomial curve, and storing the computed guidelines in the memory of the computer system.

### CROSS-REFERENCE TO RELATED APPLICATIONS

The present application claims priority to French Application No. 13 01122 filed on May 15, 2013. The entirety of the French application is incorporated herein by reference.

### FIELD OF THE INVENTION

The present invention relates to a method for building at least one aircraft guideline in an airport navigation network.

### BACKGROUND

The present invention relates to a method for building at least one aircraft guideline in an airport navigation network. The navigation network includes a plurality of polygons, is configured to be stored in a memory of a computer system, and is associated with an airport area including taxiways. Each guideline is positioned inside a corresponding polygon, and connects two separate sides of said polygon.

The invention also relates to a computer program product including software instructions which, when implemented by a computer, implement such a building method.

The invention also relates to a system for building at least one aircraft guideline in the airport navigation network.

An airport navigation network is known including a plurality of polygons, the plurality of polygons forming a model of the set of taxiways of an airport area. The navigation network can be stored in a memory of a computer system. To that end, each line is stored in the memory in the form of a sequence of points, and each polygon is stored in the form of a sequence of lines. The navigation network further includes one or more aircraft guidelines for certain polygons.

However, the navigation network includes polygons for which at least one aircraft guideline is missing, and the aircraft guidance is then more complicated on the taxiways corresponding to the polygons with one or more missing guidelines.

### SUMMARY

The aim of the invention is therefore to propose a method and a system for building at least one aircraft guideline in the airport navigation network, said guideline making it possible to improve the airport navigation network, and to thereby facilitate the guidance of aircraft in the airport area.

To that end, the invention relates to the aforementioned method, wherein the method is implemented by a computer and includes the following steps: creating nodes at each intersection between an existing guideline and a side of a corresponding polygon, or at the middle of a side shared by two polygons when no guideline is secant with said side, detecting at least one pair of nodes not connected by a guideline, computing, for each detected pair of nodes, a guideline in the form of a polynomial curve, and storing the computed guidelines in the memory of the computer system.

According to other advantageous aspects of the invention, the building method comprises one or more of the following features, considered alone or according to all technically possible combinations the detection step includes detecting at least one isolated node that is not connected to any other node; the detection step includes detecting at least one node belonging to a side shared by two polygons and connected to the other node(s) of only one of the two polygons; the polynomial curve is a Bézier curve, the Bézier curve is a Bézier curve of order 2 verifying the following equation:

B(t)=(1−t)²×P₀+2×t×(1−t)×P₁+t²×P₂

with t belonging to the interval [0, 1], and

P₀, P₁ and P₂ representing the coordinates of control points of the Bézier curve; the computation step includes computing a first Bézier curve, as control points, with the center of gravity of the corresponding polygon and the two nodes of the detected pair of nodes, and verifying the position of the first computed Bézier curve relative to the corresponding polygon, the first computed Bézier curve being stored in said memory as guideline during the storage step when it is fully positioned within the polygon; the computation step further includes, when the first computed Bézier curve is not fully positioned within the polygon: computing a second Bézier curve by replacing, as control point, the center of gravity of the polygon with a point of the segment comprised between the orthocenter of the polygon and the symmetrical point of the orthocenter relative to the center of gravity, said point further being distinct from the center of gravity, and verifying the position of the second computed Bézier curve relative to the corresponding polygon, the second computed Bézier curve being, during the storage step, stored in said memory as guideline when it is fully positioned within the polygon; the computation step further includes, when the second computed Bézier curve is not fully positioned within the polygon: cutting the corresponding polygon along the perpendicular line to the segment comprised between the two nodes of the detected pair and passing through the center of gravity of said polygon, when exactly two polygons are obtained after cutting, the two polygons then having a shared side, computing a third Bézier curve for first of the two polygons and a fourth Bézier curve for the second of the two polygons,
the third curve being computed with, as control points, the node shared by the corresponding polygon before cutting and the first polygon, the center of gravity of the first polygon, and the middle of the side shared by the first and second polygons, and
the fourth curve being computed with, as control points, the node shared by the corresponding polygon before cutting and the second polygon, the center of gravity of the second polygon, and the middle of the side shared by the first and second polygons, and
verifying the position of the third and fourth computed Bézier curves relative to the first and second polygons, the third and fourth computed Bézier curves being stored in said memory as guidelines during the storage step when they are fully positioned within the first and second polygons, respectively; the computation step further includes generating an error message when more than two polygons are obtained after cutting the corresponding polygon; the computation step further includes generating an error message when the third and fourth computed Bézier curves are not fully positioned within the first and second polygons, respectively; and the method further has a step for discretizing the computed polynomial curve into a sequence of points; the curved length, along the computed curve, between two successive points of said sequence being substantially constant; the discretization step being carried out before the storage step.

The invention also relates to a computer program product including software instructions which, when implemented by a computer, implement a method as defined above.

The invention also relates to a system for building at least one aircraft guideline in an airport navigation network, the navigation network including a plurality of polygons and being associated with an airport area including taxiways, each guideline connecting two distinct sides of said polygon, the system comprising a storage memory of the navigation network, the system further comprising: means for creating nodes at each intersection between an existing guideline and a side of a corresponding polygon, or at the middle of a side shared by two polygons when no guideline is secant with said side, means for detecting at least one pair of nodes not connected by a guideline, and means for computing a guideline in the form of a polynomial curve for each detected pair of nodes, the memory being configured to store the computed guidelines.

### BRIEF DESCRIPTION OF THE DRAWINGS

These features and advantages of the invention will appear upon reading the following description, provided solely as a non-limiting example, and done in reference to the appended drawings, in which:

FIG. 1 is a diagrammatic illustration of a building system according to the invention,

FIG. 2 is a diagrammatic illustration of part of an airport navigation network including a plurality of polygons,

FIG. 3 is a flowchart of a building method according to the invention, including a step for creating nodes, a step for detecting at least one pair of nodes not connected by a guideline, a step for computing a guideline in the form of a polynomial curve for each detected pair of nodes, and a step for storing computed guidelines in a memory,

FIG. 4 is a flowchart of the computation step of FIG. 3,

FIGS. 5 to 9 are diagrammatic views of the building of guidelines in the form of polynomial curves in different cases corresponding to the flowchart of FIG. 4,

FIG. 10 is a diagrammatic illustration of the discretization of a computed polynomial curve,

FIG. 11 is a view of the airport navigation network before building guidelines, and

FIG. 12 is a view similar to that of FIG. 11, after building guidelines using the building method according to the invention.

### DETAILED DESCRIPTION

Conventionally in the present application, the expression “substantially equal to” will express a relationship of equality to within ±5%.

In FIG. 1, a system 10 for building at least one aircraft guideline 14 in an airport navigation network 12 includes a processing unit 16, for example formed by a processor 18 and a memory 20 associated with the processor 18.

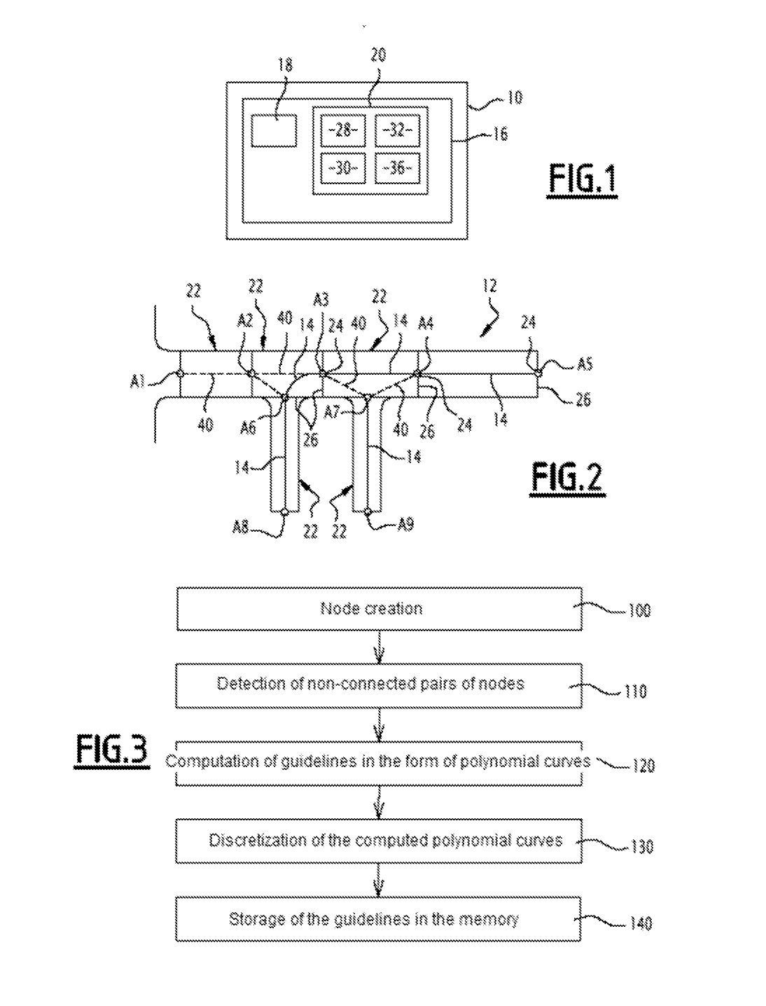

The navigation network 12, shown in FIG. 2, includes a plurality of polygons 22, and is associated with an airport area, not shown, including taxiways. The navigation network 12 is in accordance with the EUROCAE ED99C and EUROCAE ED119B standards or the subsequent versions of those standards. The navigation network 12 forms a model of all of the taxiways of the airport area.

Each guideline 14 is, according to the standards associated with the navigation network 12, positioned within a corresponding polygon 22 and connects two respective points 24, also called nodes, of two distinct sides 26 of said polygon.

The memory 20 is configured to store the airport navigation network 12 in the form of a sequence of points, each polygon 22 being stored in the form of a sequence of lines and each line being stored in the form of a sequence of points.

The memory 20 is also configured to store software 28 for creating nodes 24, software 30 for detecting at least one pair of nodes 24 not connected by a guideline 14, and software 32 for computing, for the or each detected pair of nodes 24, a guideline 14 in the form of a polynomial curve 34, the memory 20 being capable of storing the computed guideline(s) 14.

Alternatively, the creation means 28, the detection means 30 and the computation means 32 are made in the form of programmable logic components, or in the form of dedicated integrated circuits.

Additionally, the memory 20 is configured to store software 36 for discretizing the computed polynomial curve 34 in a sequence of points 38, shown in FIG. 10, the curved length between two successive points 38 of said sequence along the computed curve 34 being substantially constant.

Also alternatively, the discretization means 36 are made in the form of programmable logic components, or in the form of dedicated integrated circuits.

According to the aforementioned standards, each polygon 22 must include nodes 24 at each intersection between an existing guideline 14 and a side 26 of the polygon, or at the middle of a side 26 of the polygon when no guideline is secant with said side 26, said side 26 further being shared with another polygon 22, as shown in FIG. 2.

Each polygon 22 is a planar geometric figure formed by a plurality of segments forming a closed broken line. In other words, each polygon 22 corresponds to the standard mathematical definition of a polygon.

The nodes 24 are identified by references A1, A2, . . . , A9 in the example of FIG. 2. Among these nodes 24, some nodes are connected to a single guideline 14 at the border between two polygons 22, such as nodes A3, A7 in the example of FIG. 2. Among these nodes 24, other nodes, such as the nodes A1, A2, are isolated, i.e., are not connected to any other node 24 by a guideline 14.

The creation software 28 is configured to create nodes 24 at each intersection between an existing guideline 14 and a side 26 of the corresponding polygon, or at the middle of a side shared by two polygons 22 when no guideline is secant with said side 26.

The detection software 30 is configured to detect at least one pair of nodes 24 not connected by a guideline 14, such as the pairs of nodes (A1, A2), (A2, A3), (A2, A6), (A3, A7) and (A7, A4) in the example of FIG. 2. The detected pairs of nodes will conventionally be referenced (Ai, Aj) in the rest of the description, Ai corresponding to a first node of the pair and Aj corresponding to the second node of the pair.

The computation software 32 is configured to compute, for each detected pair of nodes (Ai, Aj), the corresponding guideline 14 in the form of the polynomial curve 34, such as a Bézier curve B(t). The Bézier curve is preferably a Bézier curve of order 2 verifying the following equation:

B(t)=(1−t)²×P₀+2×t×(1−t)×P₁+t²×P₂ (1)

with a parameter t belonging to the interval [0, 1], and Pₒ, P₁ and P₂ representing the coordinates of control points of the Bézier curve B(t).

The building system 10 according to the invention is then capable of building missing guidelines 14, in particular between each unused node A1, A2 and the other corresponding nodes A2, A6, and between the nodes A3, A7 used a single time at the border between two polygons 22 and the other corresponding nodes A2, A3, A4. In other words, the building system 10 according to the invention is capable of building a guideline 14 for each detected pair of nodes (Ai, Aj), such as the pairs of nodes (A1, A2), (A2, A3), (A2, A6), (A3, A7) and (A7, A4) in the example of FIG. 2.

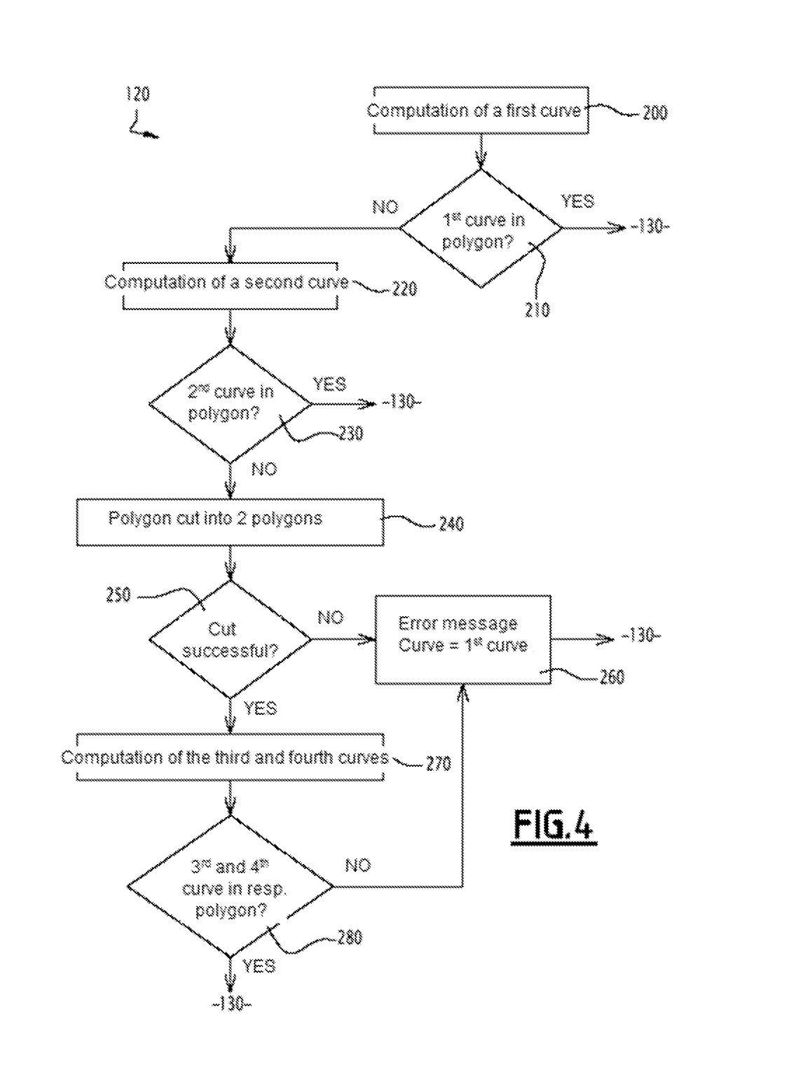

The operation of the building system 10 according to the invention will now be explained using FIGS. 3 and 4, showing flowcharts of the building method according to the invention and a computation step of said method, respectively.

During an initial step 100, the creation software 28 creates nodes 24 at each intersection between an existing guideline 14 and a side 26 of a corresponding polygon, or at the middle of a side shared by two polygons 22 when no guideline is secant with said side 26. At the end of the creation step 100, the nodes 24 are positioned at the border of two polygons 22 or at the intersection of a guideline 14 and a corresponding side 26, as shown in FIG. 2.

During this step 110, the detection software 30 then detects at least one pair (Ai, Aj) of nodes not connected by a guideline 14. In other words, the detection software 30 makes it possible to identify the polygon(s) 22 for which at least one aircraft guideline is missing, i.e., the polygons 22 for which at least two nodes 24 are not connected by a guideline 14.

In the example of FIG. 2, the detection software 30 thus determines that guidelines 14 are missing between the nodes A1 and A2, A2 and A3, respectively, A2 and A6, respectively, A3 and A7, respectively, and A7 and A4, respectively.

During the detection step 110, the detection software 30 for example begins by looking for at least one isolated node that is not connected to any other node 24, such as the isolated nodes A1, A2 in the example of FIG. 2. The detection software 30 then looks for at least one node 24 belonging to a side 26 shared by two polygons 22 and connected to the other node(s) of only one of the two polygons 22, such as the node A7 in the example of FIG. 2.

In order to define a list of connections to be established between the nodes 24, i.e., the list of pairs of nodes (Ai, Aj) to be connected by guidelines 14, the detection software 30 begins, for example, by selecting all of the detected isolated nodes A1, A2, then connects them to the other nodes A1, A3, A6 of the corresponding polygons 22 by temporary segments 40, such as the temporary segments [A1,A2], [A2,A3] and [A3,A6] in the example of FIG. 2. The nodes A1, A2 are then no longer considered isolated nodes.

The detection software 30 next selects the nodes 24 belonging to a side 26 shared by two polygons 22 and connected to the other node(s) of only one of the two polygons 22, such as the nodes A1 and A7 in the example of FIG. 2, then if possible, connects them to the other nodes A3, A4 of the other of the two corresponding polygons 22 using temporary segments 40, such as the temporary segments [A7,A3] and [A7,A4] in the example of FIG. 2.

The detected pairs of nodes (Ai, Aj) for which a guideline 14 requires computation then correspond to the temporary segments 40.

The computation software 32 then computes, during the following step 120, the guidelines 14 corresponding to the detected pairs of nodes (Ai, Aj), i.e., corresponding to the temporary segments 40. The computation step 120 will be described in more detail below using the flowchart in FIG. 4.

During step 130, the discretization software 36 next discretizes the computed polynomial curve 34 into a sequence of points 38. The discretization step 130 will be described in more detail below in light of FIG. 10. The discretization is preferably such that the curved length, along the computed curve 34, between two successive points 38 of said sequence is substantially constant.

The polynomial curves 34 computed as guidelines 14 are lastly stored, during step 140, in the memory 20 in the form of sequences of points 38 obtained after the discretization step 130.

Alternatively, the building method does not include the discretization step 130, and the building method goes directly from the computation step 120 to the storage step 140. During this step 140, the computed polynomial curve 34 is then stored in the memory 20 as a Bézier curve.

The computation step 120 will now be described in more detail using the flowchart in FIG. 4. The computation step 120 is broken down into several phases, also called sub-steps.

The computation step 120 begins with a sub-step 200 for computing a first Bézier curve B₁(t), preferably a Bézier curve of order 2 verifying the following equation:

B₁(t)=(1−t)²P_{0,1}+2×t×(1−t)×P_{1,1}+t²×P_{2,1} (2)

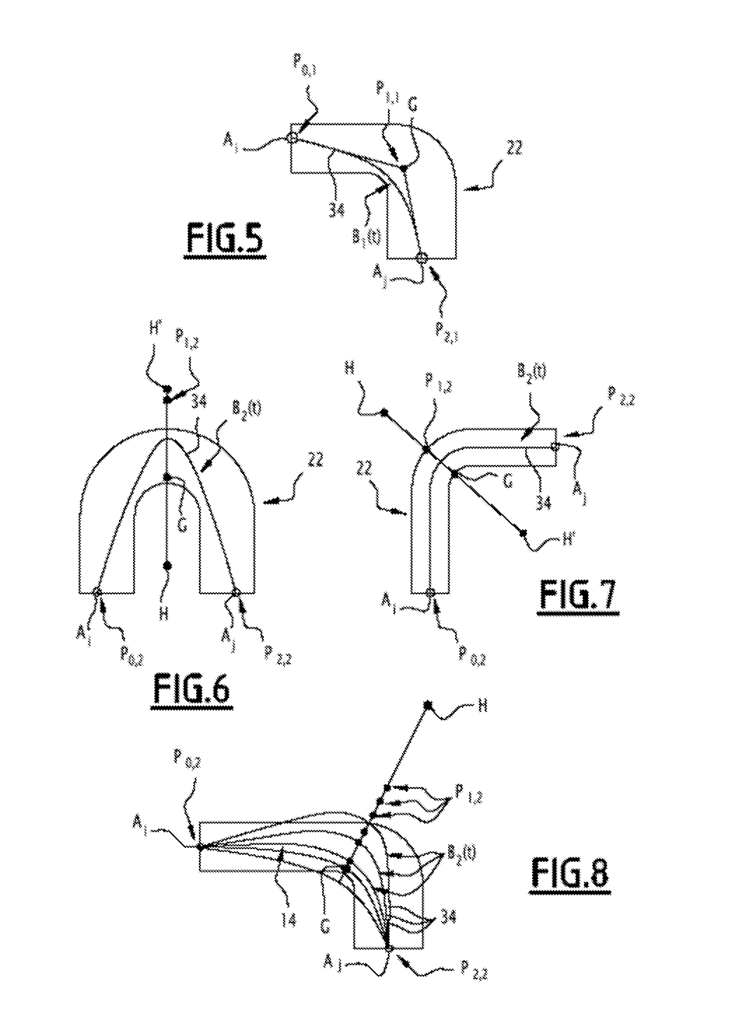

with the parameter t belonging to the interval [0, 1] and, as control points P_{0,1}, P_{1,1}, P_{2,1}, one Ai of the two nodes of the detected pair (Ai, Aj), the center of gravity G of the corresponding polygon, and the other Aj of the two nodes of the detected pair (Ai, Aj), respectively, as shown in FIG. 5.

The computation software 32 next verifies, during the sub-step 210, the position of the first computed Bézier curve Bᵢ(t) relative to the corresponding polygon 22.

When the first computed Bézier curve Bᵢ(t) is fully positioned within the polygon 22, as shown in FIG. 5, it is sent to the discretization software 36 in order to be discretized during step 130, then stored in the memory 20, during the storage step 140, as guideline 14.

When the first computed Bézier curve Bᵢ(t) is not fully positioned within the corresponding polygon 22, the computation software 32 next computes a second Bézier curve B₂(t) during a sub-step 220, preferably a Bézier curve of order 2 verifying the following equation:

B₂(t)=(1−t)²×P_{0,2}2×t×(1−t)×P_{1,2}+t²×P_{2,2} (3)

with the parameter t belonging to the interval [0, 1] and, as control points P_{0,2}, P_{1,2}, P_{2,2}, one Ai of the two nodes of the detected pair (Ai, Aj), a point of the segment [HH′] comprised between the orthocenter H of the polygon 22 and the symmetrical point H′ of the orthocenter H relative to the center of gravity G, said point further being distinct from the center of gravity G, and the other Aj of the two nodes of the detected pair (Ai, Aj), respectively, as shown in FIGS. 6 and 7.

In other words, to compute the second Bézier curve B₂(t), and in comparison with the first Bézier curve Bᵢ(t) previously computed, the center of gravity G is replaced, as control point, by a point of the segment [HH′] having for ends the orthocenter H of the polygon 22 and the symmetrical point H′ of the orthocenter H relative to the center of gravity G.

The computation software 32 next verifies, during the sub-step 230, the position of the second computed Bézier curve B₂(t) relative to the corresponding polygon 22.

When the second computed Bézier curve B₂(t) is fully positioned within the polygon 22, as shown in FIGS. 6 and 7, it is sent to the discretization software 36 in order to be discretized during that step 130, then to be stored in the memory 20, during the storage step 140, as guidelines 14.

When the second computed Bézier curve B₂(t) is not fully positioned within the corresponding polygon 22, as shown in FIG. 8 for certain polynomial curves 34, the computation software 32 begins by re-computing the second Bézier curve B₂(t) according to equation (3) and taking another point of the segment [HH′], preferably a point closer to the orthocenter H, as intermediate control point P_{1.2}.

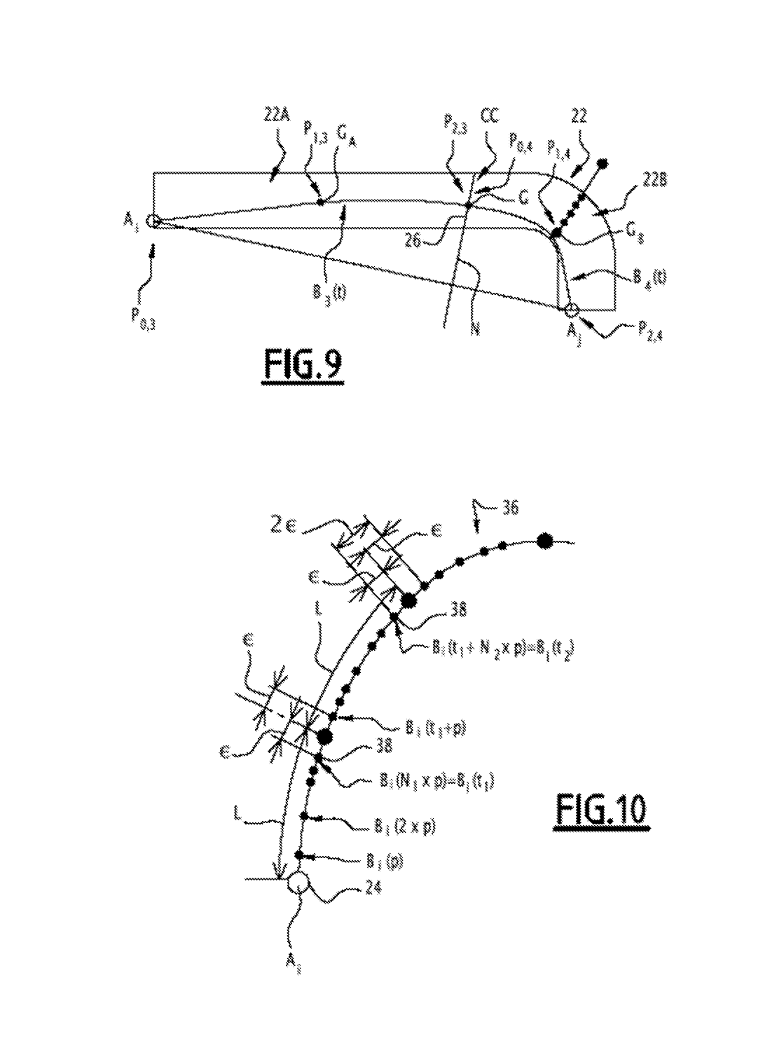

When the second computed Bézier curve B₂(t) is not fully positioned within the corresponding polygon 22, including after recomputing the second Bézier curve B₂(t), during sub-step 240 the computation software 32 cuts the corresponding polygon 22 along the perpendicular line N to the segment [AiAj] comprised between the two nodes of the detected pair (Ai, Aj) and passing through the center of gravity G of said polygon 22, as shown in FIG. 9.

The computation software 32 next verifies, during the sub-step 250, whether the cut was successful, i.e., whether only two polygons 22A, 22B are obtained after the cutting sub-step 240. If the cutting sub-step is not successful, i.e., if more than two polygons are obtained after the cutting of said polygon 22, then the computation software 32 uses the first Bézier curve Bᵢ(t) previously computed as guideline 14 and, during sub-step 260, generates an error message in order to indicate that the computed guideline 14 is not fully positioned within the corresponding polygon 22. The first computed Bézier curve Bᵢ(t) is then sent to the discretization software 36 in order to be discretized during that step 130, then stored in the memory 20, during the storage step 140, as guideline 14.

It is preferable to store, in the memory 20, a computed guideline 14 that is not fully positioned within the corresponding polygon 22, as this makes it possible to indicate that the two corresponding sides of the polygon 22 are connected to each other, the error message further indicating that the guideline is not viable. The aircraft will, however, be capable of following a path close to that guideline.

A contrario, if the computed guideline 14 that is not fully positioned within the corresponding polygon 22 had not been stored in the memory 20, then the navigation network 12 would not have been considered complete for the corresponding polygon 22, and the end of the associated taxiway would not have been proposed to the aircraft as a possible path.

When exactly two polygons 22A, 22B are obtained after the cutting sub-step 240, the two polygons 22A, 22B then having a shared side 26, denoted CC, the computation software 32 computes, during the sub-step 270, a third Bézier curve B₃(t) for a first 22A of the two polygons and a fourth Bézier curve B₄(t) for the second 22B of the two polygons, as shown in FIG. 9.

The third Bézier curve B₃(t) is preferably a Bézier curve of order 2 verifying the following equation:

B₃=(1−t)²×P_{0,3}2×t×(1−t)×P_{1,3}+t²×P_{2,3} (4)

with the parameter t belonging to the interval [0, 1] and, as control points P_{0,3}, P_{1,3}, P_{2,3}, the node Ai shared by the polygon 22 before cutting and the first polygon 22A, the center of gravity G_{A} of the first polygon 22A, and the middle of the side CC shared by the first and second polygons 22A, 22B, as shown in FIG. 9.

The fourth Bézier curve B₄(t) is preferably a Bézier curve of order 2 verifying the following equation:

B₄(t)=(1−t)²×P_{0,4}+2×t×(1−t)×P_{1,4}+t²×P_{2,4} (5)

with the parameter t belonging to the interval [0, 1] and, as control points P_{0,4}, P_{1,4}, P_{2,4}, the middle of the side CC shared by the first and second polygons 22A, 22B, the center of gravity G_{B} of the second polygon 22B, and the node Aj shared by the polygon 22 before cutting and the second polygon 22B, as shown in FIG. 9.

The last control point P_{2,3} of the third Bézier curve B₃(t) is then identical to the first control point P_{0,4} of the fourth Bézier curve B₄(t).

During the sub-step 280, the computation software 32 next verifies the position of the third B₃(t) and fourth B₄(t) computed Bézier curves relative to the first 22A and second 22B polygons, respectively.

When the third B₃(t) and fourth B₄(t) computed Bézier curves are fully positioned within the first 22A and second 22B polygons, respectively, as shown in FIG. 9, they are concatenated, i.e. placed end-to-end, in a single polynomial curve 34. Said polynomial curve 34 is next sent to the discretization software 36 in order to be discretized during this step 130, then stored in the memory 20, during the storage step 140, as guideline 14.

When at least one of the third B₃(t) and fourth B₄(t) computed Bézier curves is not fully positioned within the corresponding polygon from among the first 22A and second 22B polygons, then the computation software 32 uses the first previously computed Bézier curve Bᵢ(t) as guideline 14 and, during the sub-step 260, generates the error message in order to indicate that the computed guideline 14 is not fully positioned within the corresponding polygon 22. The first computed Bézier curve Bᵢ(t) is then sent to the discretization software 36 in order to be discretized during that step 130, then stored in the memory 20, during the storage step 140, as guideline 14.

The discretization step 130 will now be described in more detail using FIG. 10. The discretization step 130 consists of discretizing the computed polynomial curve 34 into the sequence of points 38 for the purposes of the storage step 140.

The discretization software 36 for example discretizes the computed curve Bᵢ(t), with the index i equal to 1, 2, 3 or 4 according to the preceding, by varying the value of the parameter t by a constant value pitch for the interval [0, 1]. The obtained points 38 then correspond to the different values Bᵢ(tₖ), where tₖ represents the different values of the parameter t, the index k varying between 1 and a number M of desired points 38, and the gap between two successive values tₖ, tₖ₊₁ being equal to the constant value pitch. The curved length, along the computed curve Bᵢ(t), between two successive points Bᵢ(tₖ), Bᵢ(tₖ₊₁) of said sequence will not, however, generally be constant.

Alternatively, and preferably, the different values tₖ of the parameter t are computed so as to have a curved length L, along the computed curve Bᵢ(t), that is substantially constant, to within a margin of error c, between two successive points Bᵢ(tₖ), Bᵢ(tₖ+₁) of said sequence.

The discretization software 36 begins by computing the total curved length Lₜₒₜ of the curve Bᵢ(t) between the nodes Ai and Aj, then computes the curved length L between two successive points, by dividing the total curved length Lₜₒₜ by the number M of points 38.

From strictly positive predetermined values of the margin of error ε and an iteration pitch p, as well as the computed value of the curved length L, the discretization software 36 next includes the value of an index n until the curved length between the node Ai and the point Bᵢ(n×p) is comprised in the interval [L−ε, L+ε], for a value N₁ of the index n, as shown in FIG. 10. The first value t₁ of the parameter t is then generally set equal to N₁×p, and the first point Bᵢ(t₁) of the sequence after the node Ai is the point Bᵢ(N₁×p).

The discretization software 36 then increments, starting from the point Bᵢ(t₁)=Bᵢ(N₁×p), the value of the index n restarting from 1, until the curved length between the point Bᵢ(t₁) and the point Bᵢ(t₁+n×p) is comprised in the interval [L−ε, L+ε] for a value N₂ of the index n. The second value t₂ of the parameter t is then set equal to t₁+N₂×p, and the second point Bᵢ(t₂) of the sequence after the node Ai is the point Bᵢ(t₁+N₂×p), or Bᵢ((N₁+N₂)×p).

The discretization software 36 reiterates this operation until obtaining the value t_{M} of the parameter t set equal to t_{M-1}+N_{M}×p, and after verifying that the curved length between the point Bᵢ(t_{M}) and the other node Aj is comprised in the interval [L−ε, L+ε]. The last point Bᵢ(t_{M}) of the sequence before the node Aj is then the point Bᵢ(t_{M-1}+N_{M}×p).

The points Bᵢ(t₁), Bᵢ(t₂), . . . , Bᵢ(t_{M}) are next stored in the memory during step 140.

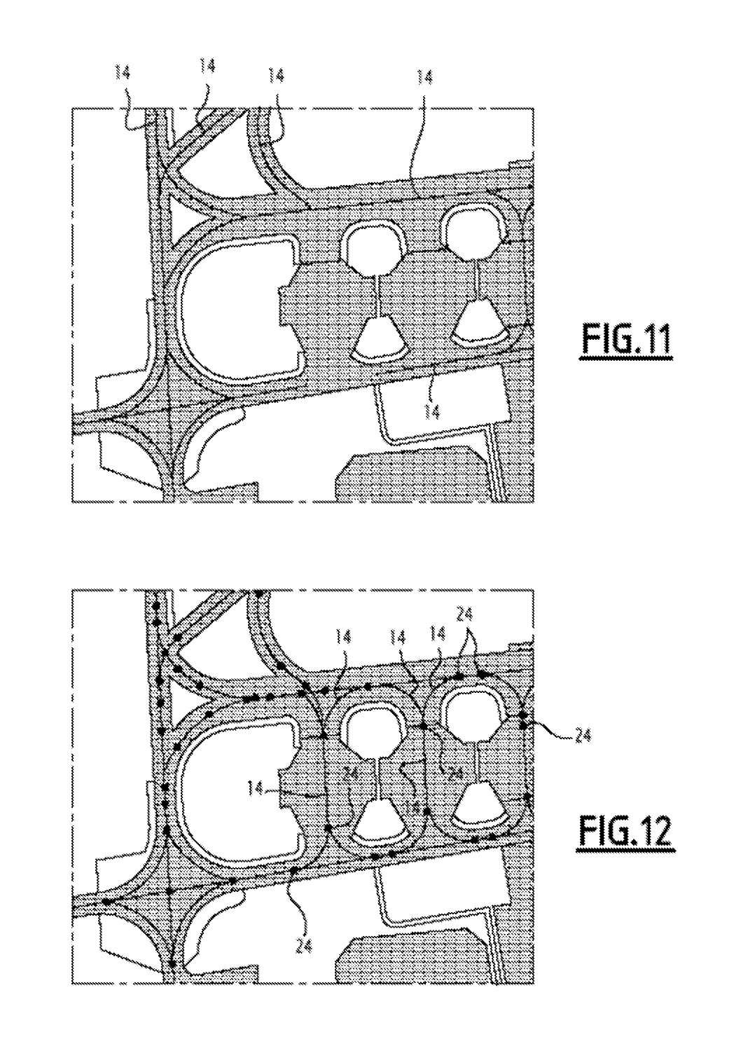

Thus, the building method and system 10 according to the invention make it possible to improve the airport navigation network, as shown by comparing FIG. 11, which shows a view of the airport navigation network before building guidelines, with FIG. 12, which shows said airport navigation network after building guidelines 14 using the method according to the invention. The set of guidelines 14 is much denser in FIG. 12 than in FIG. 11, in particular at the center of the network.

In FIG. 11, certain taxiways do not include any guidelines, whereas in FIG. 12, all of the taxiways include one or more guidelines 14.

Furthermore, when the computed polynomial curves 34 are Bézier curves, preferably Bézier curves of order 2, the created guidelines 14 have a shape particularly suited to guiding the aircraft.

Furthermore, the computation, if necessary, of the second B₂(t), or even third B₃(t) and fourth B₄(t), Bézier curves makes it possible to increase the likelihood that the created guideline 14 is fully positioned within the corresponding polygon 22.

Furthermore, the discretization of the computed curve Bᵢ(t) with a substantially constant curved length L to within a margin of error c, between two successive points Bᵢ(tₖ), Bᵢ(tₖ₊₁), makes it possible to improve the output of the created guideline 14.

It is thus possible to see that the building method and system 10 according to the invention make it possible to improve the airport navigation network, and thereby facilitate the guidance of aircraft in the airport area.

1. A method for building at least one aircraft guideline in an airport navigation network, the navigation network including a plurality of polygons and being associated with an airport area including taxiways, the or each guideline connecting two distinct sides of a corresponding polygon, the navigation network being configured to be stored in a memory of a computer system,
the method being implemented by a computer and comprising the following steps:
creating nodes at each intersection between an existing guideline and a side of a corresponding polygon, or at the middle of a side shared by two polygons when no guideline is secant with said side,
detecting at least one pair of nodes not connected by a guideline,
computing, for the or each detected pair of nodes, a guideline in the form of a polynomial curve, and
storing the computed guidelines in the memory of the computer system.

2. The method according to claim 1, wherein the detection step includes detecting at least one isolated node that is not connected to any other node.

3. The method according to claim 1, wherein the detection step includes detecting at least one node belonging to a side shared by two polygons and connected to the other node(s) of only one of the two polygons.

4. The method according to claim 1, wherein the polynomial curve is a Bézier curve.

5. The method according to claim 4, wherein the Bézier curve is a Bézier curve of order 2 verifying the following equation:
B(t)=(1−t)²×P₀+2×t×(1−t)×P₁+t²×P₂
with t belonging to the interval [0, 1], and
P₀, P₁ and P₂ representing the coordinates of control points of the Bézier curve.

6. The method according to claim 4, wherein the computation step includes:
computing a first Bézier curve with, as control points, the center of gravity of the corresponding polygon and the two nodes of the detected pair of nodes, and
verifying the position of the first computed Bézier curve relative to the corresponding polygon, the first computed Bézier curve being stored in said memory as guideline during the storage step when it is fully positioned within the polygon.

7. The method according to claim 6, wherein the computation step further includes, when the first computed Bézier curve is not fully positioned within the polygon:
computing a second Bézier curve by replacing, as control point, the center of gravity of the polygon with a point of the segment comprised between the orthocenter of the polygon and the symmetrical point of the orthocenter relative to the center of gravity, said point further being distinct from the center of gravity, and
verifying the position of the second computed Bézier curve relative to the corresponding polygon, the second computed Bézier curve being, during the storage step, stored in said memory as guideline when it is fully positioned within the polygon.

8. The method according to claim 7, wherein the computation step further includes, when the second computed Bézier curve is not fully positioned within the polygon:
cutting the corresponding polygon along the perpendicular line to the segment comprised between the two nodes of the detected pair and passing through the center of gravity of said polygon,
when exactly two polygons are obtained after cutting, the two polygons then having a shared side, computing a third Bézier curve for a first of the two polygons and a fourth Bézier curve for the second of the two polygons,
the third curve being computed with, as control points, the node shared by the corresponding polygon before cutting and by the first polygon, the center of gravity of the first polygon, and the middle of the side shared by the first and second polygons, and
the fourth curve being computed with, as control points, the node shared by the corresponding polygon before cutting and by the second polygon, the center of gravity of the second polygon, and the middle of the side shared by the first and second polygons, and
verifying the position of the third and fourth computed Bézier curves relative to the first and second polygons, the third and fourth computed Bézier curves being stored in said memory as guidelines during the storage step when they are fully positioned within the first and second polygons, respectively.

9. The method according to claim 8, wherein the computation step further includes generating an error message when more than two polygons are obtained after cutting the corresponding polygon.

10. The method according to claim 8, wherein the computation step further includes generating an error message when the third and fourth computed Bézier curves are not fully positioned within the first and second polygons, respectively.

11. The method according to claim 1, wherein the method further comprises a step for discretizing the computed polynomial curve into a sequence of points; the curved length, along the computed curve, between two successive points of said sequence being substantially constant; the discretization step being carried out before the storage step.

12. A computer program product including software instructions which, when implemented by a computer, implement the method according to claim 1.

13. A system for building at least one aircraft guideline in an airport navigation network, the navigation network including a plurality of polygons and being associated with an airport area including taxiways, each guideline connecting two distinct sides of a corresponding polygon,
the system comprising a memory of the navigation network,
wherein the system further comprises:
a node creator creating nodes at each intersection between an existing guideline and a side of a corresponding polygon, or at the middle of a side shared by two polygons when no guideline is secant with said side,
a detector detecting at least one pair of nodes not connected by a guideline, and
computing processor processing a guideline in the form of a polynomial curve, for each detected pair of nodes, the memory storing the computed guidelines.
